(19) United States
(12) Patent Application Publication
(10) Pub. No.: US 2006/0060238 A1
(43) Pub. Date: Mar. 23, 2006

(54) Process and fabrication methods for emitter wrap through back contact solar cells

(75) Inventors: Peter Hacke, Albuquerque, NM (US); James M. Gee, Albuquerque, NM (US)

Correspondence Address: PEACOCK MYERS, P.C., 201 THIRD STREET, N.W., SUITE 1340, ALBUQUERQUE, NM, 87102, US

(73) Assignee: Advent Solar, Inc., Albuquerque, NM (US)

(21) Appl. No.: 11/220,927

(22) Filed: Sep. 6, 2005

Related U.S. Application Data
(63) Continuation-in-part of application No. 11/050,185, filed on Feb. 3, 2005.
(63) Continuation-in-part of application No. 11/050,182, filed on Feb. 3, 2005.
(63) Continuation-in-part of application No. 11/050,184, filed on Feb. 3, 2005.
(60) Provisional application No. 60/607,984, filed on Sep. 7, 2004.
(60) Provisional application No. 60/707,648, filed on Aug. 11, 2005.
(60) Provisional application No. 60/542,454, filed on Feb. 5, 2004.
(60) Provisional application No. 60/542,390, filed on Feb. 5, 2004.
(60) Provisional application No. 60/542,454, filed on Feb. 5, 2004.
(60) Provisional application No. 60/542,390, filed on Feb. 5, 2004.
(60) Provisional application No. 60/542,454, filed on Feb. 5, 2004.
(60) Provisional application No. 60/542,390, filed on Feb. 5, 2004.

(51) Int. Cl. H01L 31/00

(52) U.S. Cl. 136/256; 438/98

(57) ABSTRACT

Back contact solar cells including rear surface structures and methods for making same. The rear surface is doped to form an n⁺ emitter and then coated with a dielectric layer. Small regions are scribed in the rear surface and p-type contacts are then formed in the regions. Large conductive grid areas overlay the dielectric layer. The methods provide for increasing efficiency by minimizing p-type contact areas and maximizing n-type doped regions on the rear surface of a p-type substrate.

### CROSS-REFERENCE TO RELATED APPLICATIONS

This application claims priority to and the benefit of the filing of U.S. Provisional Patent Application Ser. No. 60/607,984, entitled “Improved Process and Fabrication Methods for Emitter Wrap Through Back Contact Solar Cells,” filed on Sep. 7, 2004, and U.S. Provisional Patent Application Ser. No. 60/707,648, entitled “Further Improved Process and Fabrication Methods for Emitter Wrap Through Back Contact Solar Cells,” filed on Aug. 11, 2005. This application is also a continuation-in-part application of the following U.S. Patent Applications, all of which were filed on Feb. 3, 2005: Ser. No. 11/050,185, entitled “Back-Contact Solar Cells and Methods for Fabrication”; Ser. No. 11/050,182, entitled “Buried-Contact Solar Cells With Self-Doping Contacts”; and Ser. No. 11/050,184, entitled “Contact Fabrication of Emitter Wrap-Through Back Contact Silicon Solar Cells”, which applications claim the benefit of the filing of U.S. Provisional Patent Application Ser. No. 60/542,390, entitled “Fabrication of Back-Contact Silicon Solar Cells”, filed on Feb. 5, 2004, and of U.S. Provisional Patent Application Ser. No. 60/542,454, entitled “Process for Fabrication of Buried-Contact Cells Using Self-Doping Contacts”, filed on Feb. 5, 2004. The specifications and claims of all said applications are incorporated herein by reference as if set forth in full.

### BACKGROUND OF THE INVENTION

1. Field of the Invention (Technical Field)

The present invention relates to methods and processes for fabricating a back-contact silicon solar cell, and solar cells made by such methods.

2. Background Art

Back-contact silicon solar cells have several advantages compared to conventional silicon solar cells with contacts on both the front and rear surfaces. The first advantage is that back-contact cells have a higher conversion efficiency due to reduced or eliminated contact obscuration losses (sunlight reflected from contact grid is unavailable to be converted into electricity). The second advantage is that assembly of back-contact cells into electrical circuits is easier, and therefore cheaper, because both polarity contacts are on the same surface. As an example, significant cost savings compared to present photovoltaic module assembly can be achieved with back-contact cells by encapsulating the photovoltaic module and the solar cell electrical circuit in a single step. The last advantage of a back-contact cell is better aesthetics through a more uniform appearance. Aesthetics is important for some applications, such as building-integrated photovoltaic systems and photovoltaic sunroofs for automobiles.

A generic back-contact solar cell is illustrated in FIG. 1. The silicon substrate may be n-type or p-type. One of the heavily doped emitters (n⁺⁺ and p⁺⁺) may be omitted in some designs. Alternatively, the heavily doped emitters can directly contact each other on the rear surface in other designs. Rear-surface passivation helps reduce loss of photogenerated carriers at the rear surface, and helps reduce electrical losses due to shunt currents at undoped surfaces between the contacts. The illustration only highlights features on the back surface.

There are several approaches for making a back-contact silicon solar cell. These approaches include metallization wrap around (MWA), metallization wrap through (MWT), emitter wrap through (EWT), and back-junction structures. MWA and MWT have current collection grids on the front surface. These grids are, respectively, wrapped around the edge or through holes to the back surface in order to make a back-contact cell. The EWT cell wraps the current-collection junction (“emitter”) from the front surface to the rear surface through doped conductive channels in the silicon wafer. “Emitter” refers to a heavily doped region in a semiconductor device. Such conductive channels can be produced by, for example, drilling holes in the silicon substrate with a laser and subsequently forming the emitter inside the holes at the same time as forming the emitter on front and rear surfaces. The back-junction cells have both the negative and positive polarity collection junctions on the rear surface of the solar cell. Because most of the light is absorbed—and therefore also most of the carriers are photogenerated—near the front surface, back-junction cells require very high material quality so that carriers have sufficient time to diffuse from the front to the rear surface with the collection junctions on the rear surface. In comparison, the EWT cell maintains a current collection junction on the front surface, which is advantageous for high current collection efficiency. The EWT cell is disclosed in U.S. Pat. No. 5,468,652, Method Of Making A Back Contacted Solar Cell, to James M. Gee, incorporated here in full. The various other back contact cell designs have also been discussed in numerous technical publications.

In addition to U.S. Pat. No. 5,468,652, two other U.S. patents on which Gee is a co-inventor disclose methods of module assembly and lamination using back-contact solar cells, U.S. Pat. No. 5,951,786, Laminated Photovoltaic Modules Using Back-Contact Solar Cells, and U.S. Pat. No. 5,972,732, Method of Monolithic Module Assembly. Both patents disclose methods and aspects that may be employed with the invention disclosed herein, and are incorporated by reference as if set forth in full. U.S. Pat. No. 6,384,316, Solar Cell and Process of Manufacturing the Same, discloses an alternative back-contact cell design, but employing MWT, wherein the holes or vias are spaced comparatively far apart, with metal contacts on the front surface to help conduct current to the rear surface, and further in which the holes are lined with metal.

Eikelboom et al., “Conductive Adhesives for Interconnection of Busbarless Emitter Wrap-Through Solar Cells on a Structured Metal Foil”, presented at the 17^{th} European Photovoltaic Solar Energy Conference, Munich, Germany, 22-26 Oct. 2001, discloses a process for making solar cells using a co-fired Ag/Al-alloyed p-type contact and illustrated in FIGS. 2-5, as follows:
1. Etch and clean p-type silicon wafer 2.
2. Light POCl₃ (n+) diffusion 4 (100 ohms/sq) on both surfaces.
3. HF etch and clean.
4. Deposit SiN layers 6 on both surfaces as a diffusion barrier. The solar cell at this stage is pictured in FIG. 2.
5. Laser drill holes 8 for n-type contacts and scribe grooves 10 for p-type contacts.
6. Laser damage etch and clean. The solar cell at this stage is pictured in FIG. 3.
7. Heavy POCl₃ diffusion for diffusing phosphorous into the solar cell in order to form n++ diffusions 12. The solar cell at this stage is pictured in FIG. 4.
8. HF etch.
9. Print Al paste for p-type grid 16.
10. Print metallic paste for n-type grid 18.
11. Co-fire contacts. A p⁺ Al-alloyed junction 20 overdopes the previous n⁺⁺ diffusion in the p-contact groove. The solar cell at this stage is pictured in FIG. 5.
   The resulting cell suffered from significantly poor conductivity of the alloyed-Al grid.

A critical issue for any back-contact silicon solar cell is developing a low-cost process sequence that also electrically isolates the negative and positive polarity grids and junctions. The technical issue includes patterning of the doped layers (if present), passivation of the surface between the negative and positive contact regions, and application of the negative and positive polarity contacts.

### BRIEF SUMMARY OF THE INVENTION

The present invention is a method for making a back-contact solar cell, the method comprising the steps of providing a semiconductor substrate comprising a first conductivity type, providing a diffusion comprising an opposite conductivity type on the rear surface, depositing a dielectric layer on the rear surface, forming a plurality of holes extending from a front surface of the substrate to a rear surface of the substrate, removing the diffusion and dielectric layer from one or more regions of the rear surface, creating one or more contacts comprising the first conductivity type in each of the one or more regions, disposing a first conductive grid on the rear surface in electrical contact with the contacts; and disposing a second conductive grid on the rear surface in electrical contact with the diffusion in the holes. The creating step preferably comprises doping the substrate with a dopant which preferably comprises an element selected from the group consisting of boron and aluminum. The first conductive grid preferably does not comprise the dopant. The step of providing a diffusion preferably comprises exposing the substrate to a gas which preferably comprises POCl₃. The first conductive grid is preferably interdigitated with the second conductive grid.

Optionally the depositing step comprises depositing the dielectric layer on the front surface and the creating step comprises simultaneously providing a second diffusion comprising an opposite conductivity type on the interior surfaces of the holes. The method optionally further comprises the step of constructing a passivation layer on one or both of the front surface and the rear surface, preferably using a method selected from the group consisting of oxidizing the surface or depositing the passivation layer on the surface.

The method optionally further comprises the step of coating the interior surfaces of the holes and the one or more region with a plated metallic contact layer preferably comprising nickel, wherein the coating step is performed after the creating step and prior to the disposing steps. The contact layer is preferably plated using electroless plating. This method optionally further comprises the step of providing a second diffusion after the removing step, the second diffusion comprising an opposite conductivity type on the interior surfaces of the holes and the one or more regions, and wherein the creating step comprises overdoping the second diffusion.

This invention is also a back contact solar cell made according to any of the preceding methods. This invention is further a back contact solar cell comprising a plated layer comprising a metal, preferably comprising nickel, the layer disposed between one or more doped regions of the substrate and one ore more conductive grids, wherein the conductive grids do not comprise the metal.

This invention is also a back contact solar cell and method for making a back-contact solar cell comprising the steps of providing a semiconductor substrate comprising a first conductivity type, depositing a patterned dielectric layer on the rear surface, providing a diffusion comprising an opposite conductivity type on open portions of the rear surface not covered by the dielectric layer, disposing a metal on the open portions and on the dielectric layer adjacent to the open portions, firing the metal. The depositing step preferably comprises screen printing the dielectric layer. The step of providing a diffusion preferably comprises using a gas selected from the group consisting of POCl₃ and PH₃. The metal preferably comprises a dopant of the first conductivity type. The disposing step preferably comprises screen printing a paste comprising the metal. The firing step preferably comprises spiking the diffusion in the open portions with the metal.

An object of the present invention is to provide a rear surface contact structure for back-contact solar cells comprising wide grid lines for increased conduction combined with a minimum of p-type contact areas and a maximum of n-type diffusion, or n⁺ emitter, for increased efficiency.

An advantage of the present invention is that it provides for manufacturing processes with fewer, more economical process steps that produce high efficiency solar cells.

Other objects, advantages and novel features, and further scope of applicability of the present invention will be set forth in part in the detailed description to follow, taken in conjunction with the accompanying drawings, and in part will become apparent to those skilled in the art upon examination of the following, or may be learned by practice of the invention. The objects and advantages of the invention may be realized and attained by means of the instrumentalities and combinations particularly pointed out in the appended claims.

### BRIEF DESCRIPTION OF THE SEVERAL VIEWS OF THE DRAWINGS

The accompanying drawings, which are incorporated into and form a part of the specification, illustrate one or more embodiments of the present invention and, together with the description, serve to explain the principles of the invention. The drawings are only for the purpose of illustrating one or more preferred embodiments of the invention and are not to be construed as limiting the invention. The drawings and their components are not necessarily to scale. In the drawings:

FIG. 1 is a cross section of a generic back-contact solar cell.

FIGS. 2 through 5 are cross sections depicting a solar cell manufactured according to the method as described in Eikelboom et al.

FIGS. 6 through 8 are cross sections depicting a solar cell manufactured according to a boron-diffused EWT cell process of the present invention.

FIGS. 9 through 10 are cross sections depicting a solar cell manufactured according to the boron-diffused EWT cell process of the present invention additionally with plated nickel (Ni) contacts.

FIGS. 11 through 13 are cross sections depicting a solar cell of the present invention comprising Al-alloyed p-type junctions with Ni contacts.

FIGS. 14 through 17 are cross sections depicting a solar cell of the present invention made using a double scribing method.

FIG. 18 is a schematic cross section of an embodiment of the present invention wherein the p-type metal spikes the n+ diffusion.

FIG. 19A is a plan view of a back-contact solar cell with interdigitated grid pattern. Grids with different shadings correspond to negative and positive conductivity type grids. Bond pads are provided on edge of cell for interconnection of solar cells into an electrical circuit. Illustration is not to scale; typically there is a much higher density of grid lines than is illustrated.

FIG. 19B is a cross sectional view of the interdigitated grids in an IBC cell of FIG. 15A.

FIG. 20 is a plan view of a back-contact solar cell IBC grid pattern with busbars at the edge and in the center of the cell.

FIG. 21 is cross sectional view of multilevel metallization for a back-contact solar cell.

FIG. 22 is a plan view of a back-contact solar cell IBC grid pattern of this invention.

FIG. 23 is a cross-sectional view of back-contact solar cell IBC grid with plated metallization.

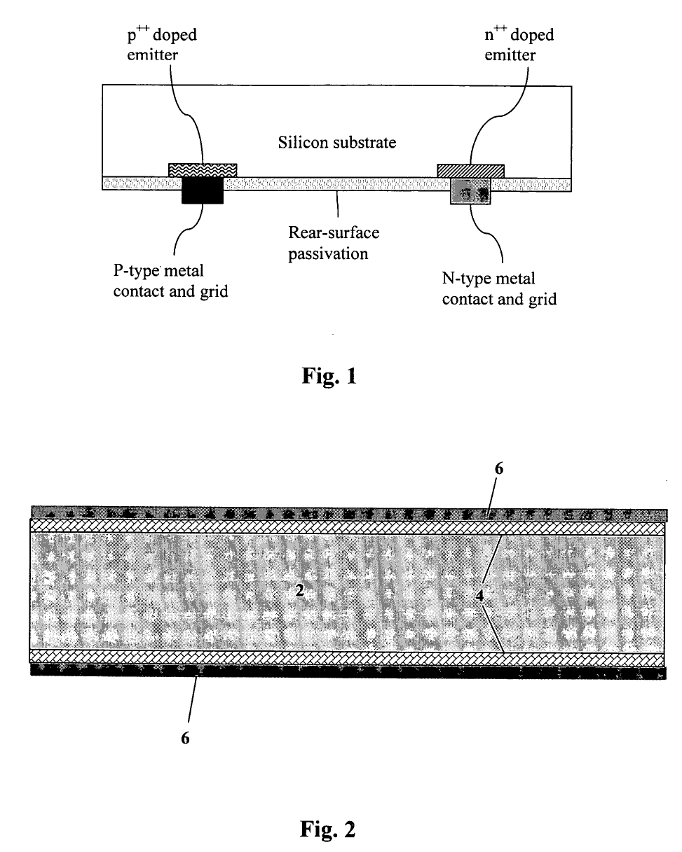

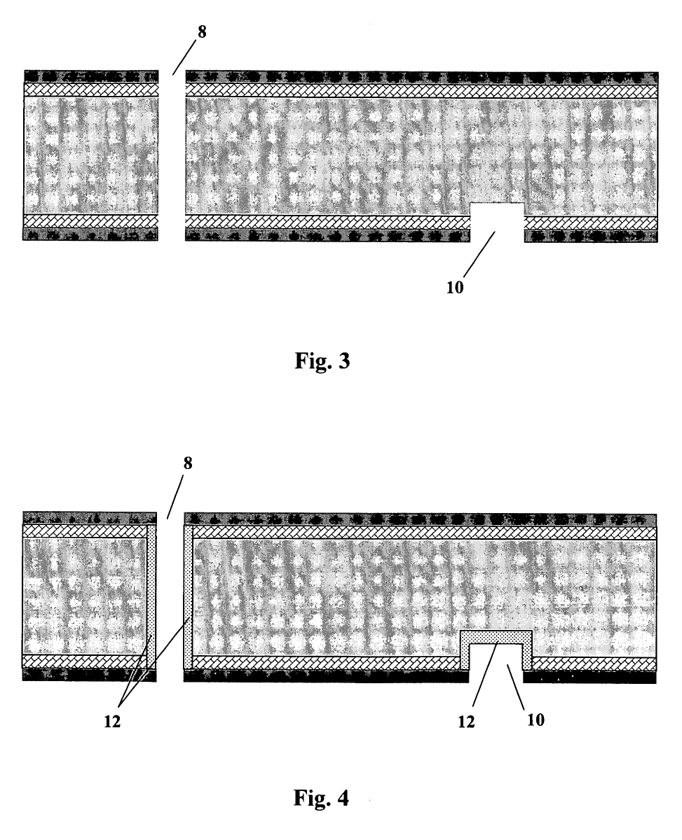

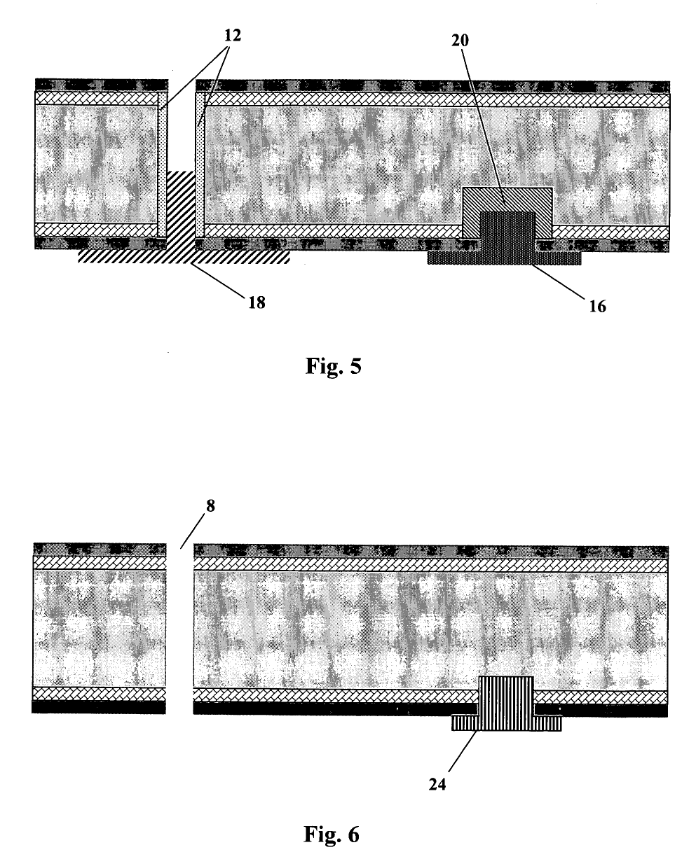

### DETAILED DESCRIPTION OF THE INVENTION

The invention disclosed herein provides for improved methods and processes for fabrication of back-contact solar cells, particularly methods and processes providing for more economical fabrication. It is to be understood that while a number of different discrete methods are disclosed, one of skill in the art could combine or vary two or more methods, thereby providing an alternative additional method of fabrication. It is also to be understood that while the figures and example process sequences describe fabrication of back-contact emitter-wrap-through cells, these process sequences can be used for fabrication of other back-contact cell structures such as MWT, MWA, or back-junction solar cells.

The processes of the present invention preferably use a laser to pattern the p-type contact (laser scribing) rather than a printed (i.e. screen-printed) diffusion barrier material applied in the desired pattern. Patterning a screen-printed diffusion barrier provides a low-quality interface, e.g. one with poor passivation, with the silicon wafer. By laser scribing the contact areas, a deposition process such as evaporation or CVD may be used to deposit the diffusion barrier, allowing the interface with the silicon to be “tuned” as desired. Also, in standard screen-printing processes, the diffusion barrier is typically printed before the phosphorous or POCl₃ diffusion is performed. By depositing the diffusion barrier after the phosphorous diffusion, the emitter can extend all of the way to the p-contact groove, greatly improving the efficiency of the cell. Other methods of scribing or direct patterning, for example dicing saw, diamond scribing, or HF etchant paste applied by screen or ink-jet printing, may optionally be used.

There are several other advantages to using a laser for patterning the p-type contact. First, laser patterning can achieve much finer geometries and resolutions, preferably 1 to 100 μm, with a most preferable range of 10 to 100 μm, than can be easily achieved with screen printing, especially for the rough surfaces typical of silicon solar cells. These finer geometries mean that the efficiency of the EWT cell can be maximized by minimizing the area of the p-type contact. Second, the registration tolerances are relaxed for the printing steps. The Ag grids (preferably 100 to 1000 μm wide and nominally 400-μm wide) need only to cover the laser-drilled holes and laser-scribed grooves (10 to 100 μm and nominally 50 μm wide), leaving a large tolerance for error in the alignment. In contrast, the all-printed sequence requires alignment of the Ag grid into a diffusion barrier opening of preferably 150 to 300 μm and nominally 200 μm. This number is much closer to the Ag grid width and leaves relatively little room for error.

Sequences using either Al alloy or boron diffusion for doping the p-type contacts are disclosed herein; however, other p-type dopants may be used, including but not limited to Ga and In. Similarly, any n-type dopant may be used alternatively to phosphorus. For the present invention, some type of heavy p-type doping in the p-type contacts is preferably used in order to electrically isolate the p-type contact from the n-type diffusion on the rear surface. The dominant processing issue is shunting of the n-type and p-type diffusions at their junction, which could also be affected by the p-type metallization.

FIGS. 6-8 illustrate a solar cell made according to the following boron-diffused process.
1. Etch and clean wafer.
2. Light POCl₃ diffusion (preferably approximately 70 to 140 ohms/sq) on both surfaces.
3. HF etch and clean.
4. Oxidize or deposit passivation layer (optional). This layer may be desirable for the front surface, the rear surface, the wafer sides, or any combination thereof.
5. Deposit SiN on both surfaces as a diffusion barrier.
6. Laser drill holes for n-type contacts and scribe grooves or pits for p-type contacts.
7. Laser damage etch and clean, preferably using NaOH.
8. Print, dry, and fire boron-containing paste 24 within and over p-type grooves or pits. The solar cell at this stage is depicted in FIG. 6.
9. Perform a heavy POCl₃ diffusion (10 to 20 ohms/sq) for diffusing phosphorous into the solar cell in order to form n++ diffusions 12, or alternatively apply a P-containing paste to holes and diffuse.

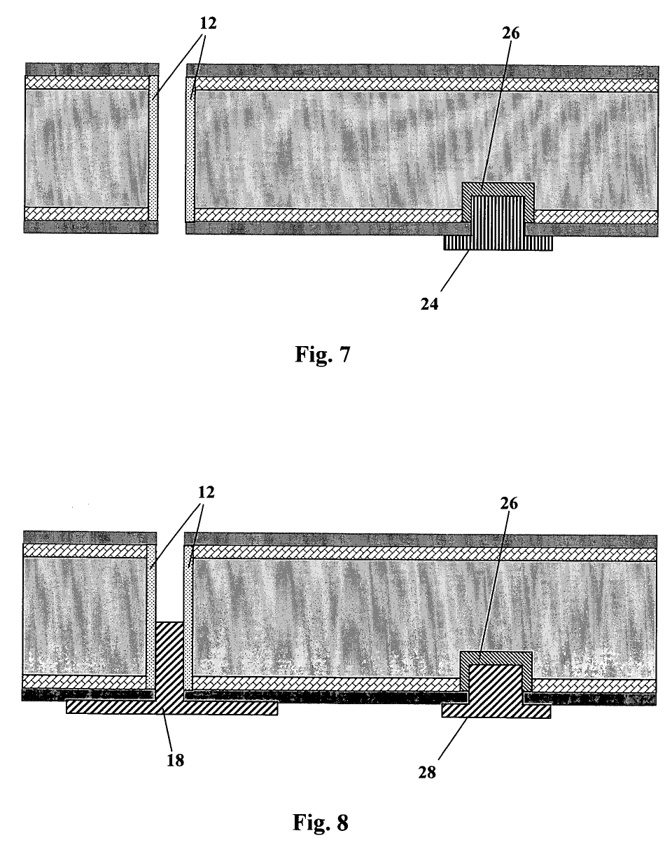

The boron preferably simultaneously diffuses into the wafer, creating p⁺⁺ layer 26. One advantage of using a POCl₃ diffusion rather than a phosphorous paste in the holes is that the POCl₃ gas provides a more uniform diffusion within the holes. The solar cell at this stage is depicted in FIG. 7.
10. HF etch (optional in certain cases) in order to remove the boron-containing paste and the P-containing paste (if used).
11. Print interdigitated Ag n metallization grid 18 and p metallization grid 28 to make contact to the n-type and p-type regions respectively.
12. Co-fire contacts. The solar cell at this stage is depicted in FIG. 8.
   Note that in this process the two Ag-containing pastes will preferably have sufficiently low activity to not form pinhole defects in the SiN layer but still have sufficient activity to make good electrical contact to the n⁺⁺ and p⁺⁺ layers inside the holes and grooves, respectively. The SiN layer can be made as thick as needed to prevent the paste from penetrating it; the layer is preferably between approximately 30 nm and 140 nm thick, and most preferably approximately 80 nm thick.

The contact layer may optionally comprise a high-quality metallization deposited by thin-film deposition techniques, including but not limited to sputtering, CVD, or evaporation. These techniques deposit very thin layers of pure metals with ideal properties for contacting silicon. The problem is that thin-film deposition is relatively costly and requires a separate patterning step. A process using thin-film and plated metallization for back-contact silicon solar cells has been described by Mulligan, et al. (U.S. Patent Application, “Metal contact structure for solar cell and method of manufacture,” US 2004/0200520 A1, Oct. 14, 2001).

The contact layer may alternatively comprise nickel plating. Sintered Ni contacts have much lower contact resistance than fired Ag-paste contacts, and can be easily deposited selectively on exposed Si surfaces by electroless Ni plating. The Ni typically undergoes a solid-state reaction to form a nickel silicide during the sintering step, in which case the nickel silicide is the contact layer. The Ni contact may have fewer problems with shunting of the junction than fired Ag contacts. Further, by optimizing the plating process, the Ni can be prevented from depositing on the existing SiN (or other dielectric) layer. Electroless Ni is used in some silicon solar cell fabrication sequences that entirely use plated metallizations. An additional advantage is that the Ni plating improves the interface so that Ag, Al, or other paste may be used to form a contact with higher integrity.

One of the problems with electroless plating for the all-plated metallization cell technologies is that electroless plating is very slow. However, the present invention requires only a thin layer, preferably approximately 10 to 1000 nm (and most preferably approximately 100 nm) thick, for the electrical contact. A screen-printed Ag grid is then preferably applied for the conductor. For this application, a Ag paste that fires at a low temperature is preferably used to minimize metallurgical interaction with the Ni contact and the underlying silicon. A screen-printed Cu grid may alternatively be used, although because Cu tends to oxidize more easily than Ag, it is preferably capped with a non-oxidizing metal or oxidation inhibitor. Alternatively, a base metal, such as Ni, can be printed and the conductivity then increased by plating (electroless or electroplating) a more conductive metal, including but not limited to Ag or Cu.

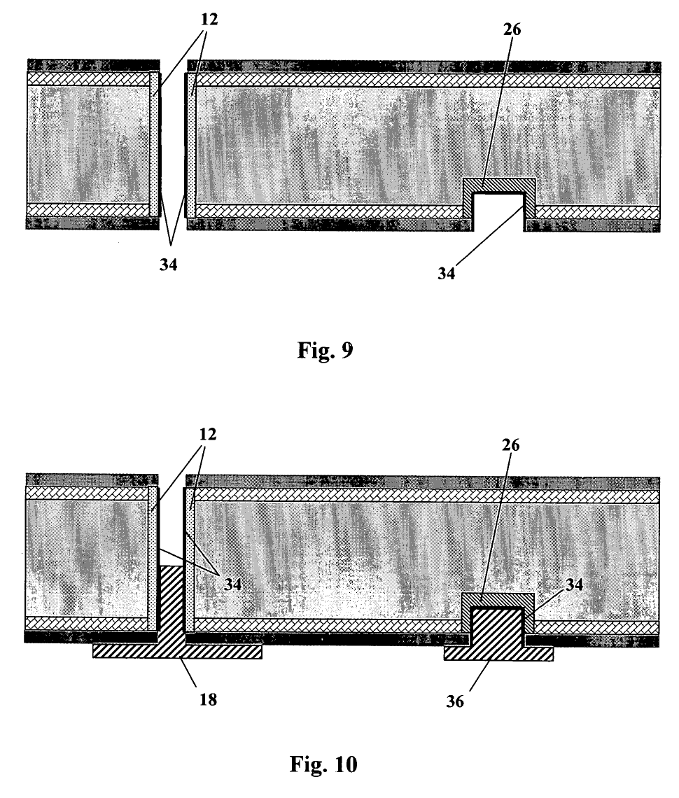

When nickel plating is incorporated into the previous boron-diffused EWT process in order to make nickel plated contacts, after the HF etch in step 10 the following steps are preferably taken:
11. Plate (preferably electroless) and preferably sinter Ni contact layers 34. The solar cell at this stage is shown in FIG. 9.
12. Print Ag n-type grid 18 and Ag p-type grid 36 (preferably using low-temperature Ag paste for both polarity grids) and fire/sinter contacts. In this embodiment, the same metal is preferably used for both the n-type and p-type contacts; alternatively, different materials may be used. The solar cell at this stage is shown in FIG. 10. Thick contacts of silver or other metal(s) may be printed, or thin contacts may alternatively be printed with further metallization built up preferably using electroless plating or electroplating. The subsequent metallization does not necessarily comprise the same metal or alloy that was previously printed.

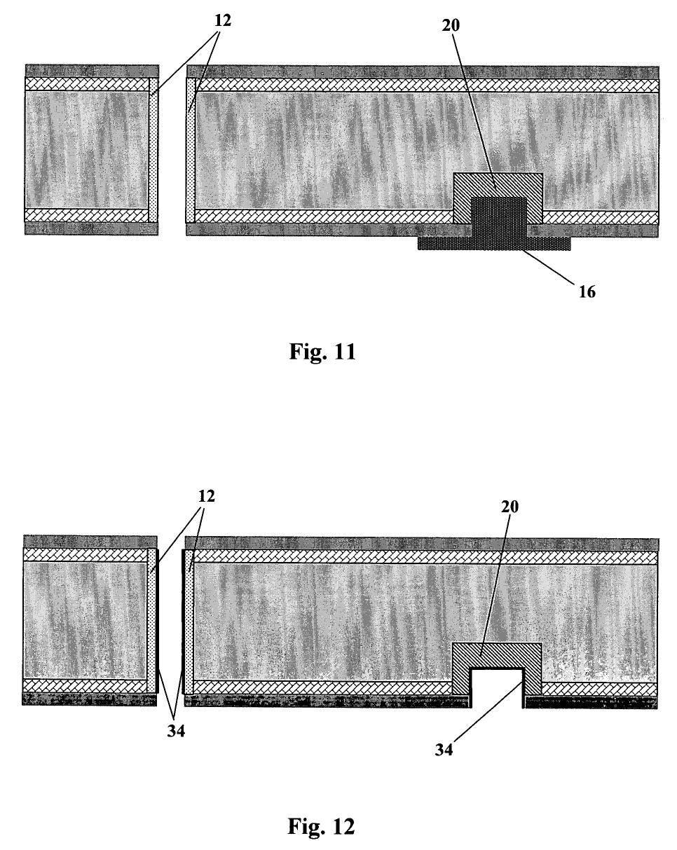

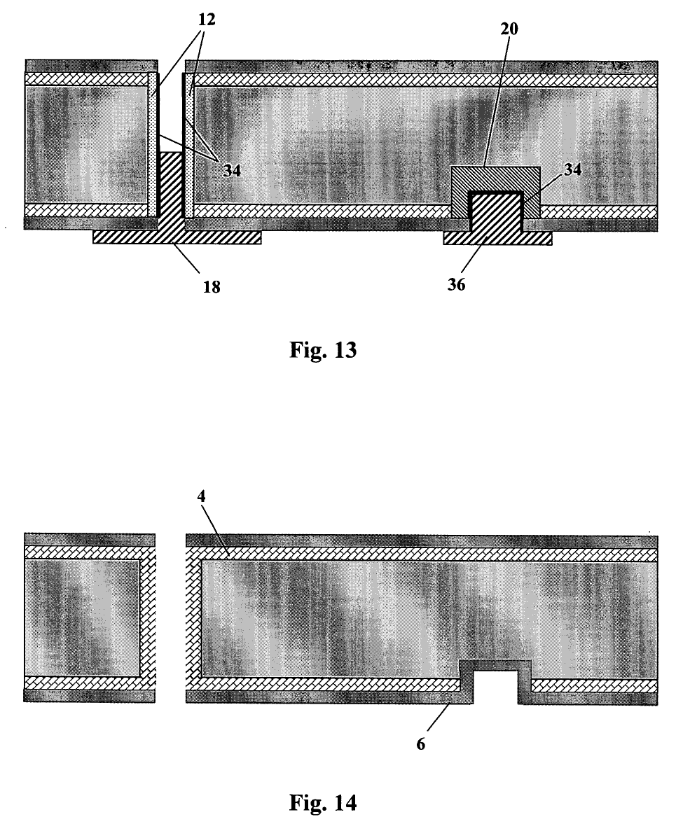

Nickel plated contacts may also be used in conjunction with an Al-alloyed p-type junction, as illustrated in FIGS. 11-13. The preferred steps comprise:
1. Etch and clean wafer.
2. Light POCl₃ diffusion (preferably approximately 70 to 140 ohms/sq) on both surfaces.
3. HF etch and clean.
4. Oxidize or deposit passivation layer on one or more surfaces or sides(optional)
5. Deposit SiN on both surfaces as a diffusion barrier.
6. Laser drill holes for n-type contacts and scribe grooves or pits for p-type contacts.
7. Laser damage etch and clean, preferably using NaOH.
8. Heavy POCl₃ diffusion (preferably approximately 10 to 30 ohms/sq), or apply P-containing paste to holes and diffuse.
9. Print Al paste for p-type grid 16.
10. Alloy Al to form junction 20 which overdopes the previous n⁺⁺ diffusion in the p-contact grooves or pits. The solar cell at this stage is shown in FIG. 11.
11. HCl and HF etch to remove Al metal and surface oxides.
12. Perform (electroless) Ni plating.
13. Sinter to form Ni contact 34. The solar cell at this stage is shown in FIG. 12.
14. Print Ag n-type grid 18 and Ag p-type grid 36 (preferably using low-temperature Ag paste for both polarity grids) and fire/sinter contacts (or alternatively build up metallization with electroless or electroplated metallization). The solar cell at this stage is shown in FIG. 13.
   Ni makes a low-resistance contact to doped Si, which allows the minimization of the p-type contact area and the use of low-temperature Ag. A low-activity Ag paste is desired so that the SiN and Ni silicide layers are not penetrated.

In the methods of the present invention, there is a potential shunt where the heavy p⁺ contact diffusion contacts the rear-surface n⁺ diffusion; see for example FIGS. 10 and 13. In addition, the positive-polarity Ag grid potentially makes contact to the rear surface n⁺ diffusion, thereby shunting the solar cell. Optimally there is no shunting because the two materials form a P—N junction diode, and there is no spiking and only minimal tunneling. However, these problems can be avoided entirely by including an additional step to place an undoped region between the rear-surface n⁺ diffusion and the p⁺ contact diffusion, preferably using a low-cost process like screen printing. One example of a process is as follows:
1. Etch and clean silicon wafer;
2. Print paste that forms dielectric material;
3. Fire paste to form dielectric;
4. Clean and etch surface (optional);
5. Perform light (for example, 70 to 150 ohms/sq) phosphorus diffusion on both surfaces;
6. Etch oxide;
7. Deposit silicon nitride on both surfaces. Other dielectric materials (including but not limited to TiO₂ or Ta₂O₅) with a large refractive index, compatibility with silicon processing, and good interfacial properties with silicon may alternatively be used.
8. Laser drill holes for the n-type vias and scribe either pits or grooves for the p-type contact;
9. Etch and clean laser-ablated features;
10. Print boron or other p-type dopant diffusion source into p-type laser-ablated features;
11. Perform heavy (for example, 5 to 30 ohms/sq, and preferably <20 ohms/sq) phosphorous diffusion to dope n-type vias and to drive boron into p-type contact openings;
12. Etch diffusion glasses; and
13. Apply and anneal negative- and positive-polarity grids

Another method for separating the p⁺ and n⁺ regions to avoid shunting preferably comprises the following steps:

1. Drill holes in a p-type silicon wafer, preferably using a laser.

2. Etch and clean the wafer. This step may comprise an alkaline etch, or optionally comprises an acidic etch to texture the front surface for improved absorption.

3. Diffuse the surface of the wafer to form n-type layer 104, preferably using POCl₃ or another n-type source, and preferably in the range of approximately 45-140 ohm/sq.

4. Etch diffusion glass.

5. Scribe openings for the p-contacts on rear surface using a laser, etching paste, a mechanical method, or the like. Preferably, this step does not introduce defects into the silicon, because there is no opportunity to etch them off.

6. Deposit patterned dielectric layer 106 preferably comprising SiN, an oxide of titanium or tantalum, or the like on the front and back surfaces of the wafer, preferably ranging from approximately 40 nm to 150 nm in thickness. This layer preferably acts as a metallization and diffusion barrier on the rear surface as well as an optical coating on both the front and rear surfaces. This layer is preferably not deposited on or in the holes. The solar cell at this stage is shown in FIG. 14.

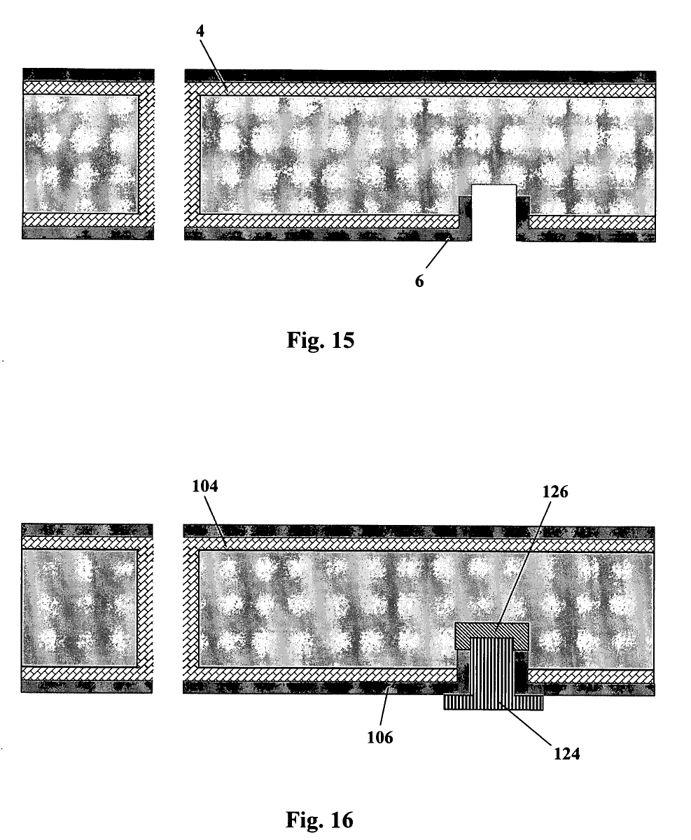

7. Perform a second scribe, directly aligned and centered with the first scribe, but having a smaller diameter or width. The solar cell at this stage is shown in FIG. 15.

8. Screen print p-type dopant paste 124, such as a boron-containing paste, in the scribed area and form p⁺ contact layer 126 in the second scribed opening by diffusion or alloying. The solar cell at this stage is shown in FIG. 16.

9. Etch boron glass or other p-type source if necessary.

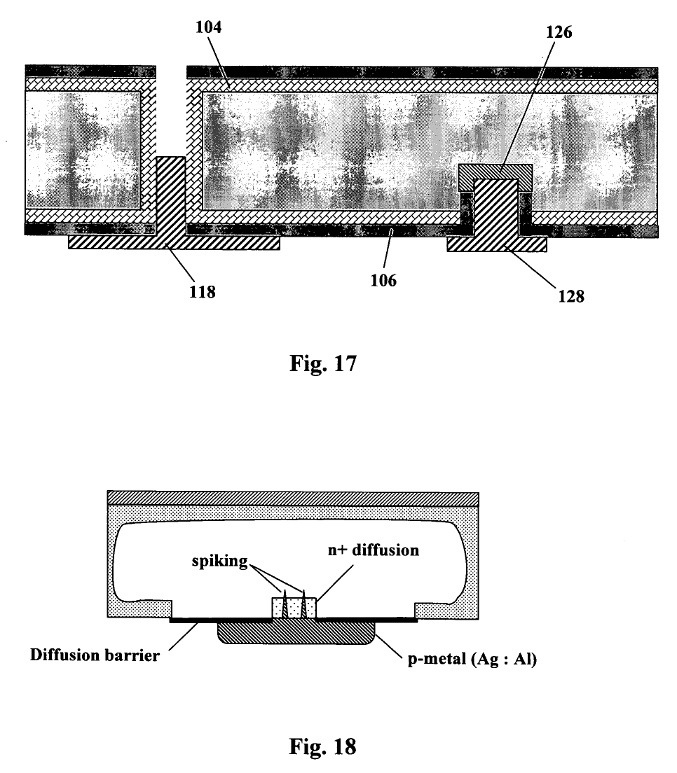

10. Metallize p grids 128 and n grids 118 with conductor paste or metal plating. The solar cell at this stage is shown in FIG. 17.

This method results in the p+ region, which is formed approximately only on the small portion of the wafer created by the second scribing step, being separated from the n+ region on the rear surface by that portion of the dielectric layer located within the first scribe.

Another preferred process of the present invention does not use a separate patterning step for the p-type contact. Rather, the p-type contact region is defined at the same time as the patterning is performed for the phosphorus diffusion. This process preferably comprises the following steps:
1. Laser drill holes.
2. Etch and clean the wafer. This step optionally comprises an alkaline etch, or optionally comprises an acidic etch to texture the front surface for improved absorption.
3. Screen print on the rear surface a dielectric material that forms a diffusion barrier pattern (not adjacent to the holes). This forms a patterned phosphorus diffusion during the phosphorus diffusion step. The pattern preferably includes openings for the subsequent p-type metal contact, particularly if the dielectric diffusion barrier cannot be easily etched and the p-type metal does not easily fire through the diffusion barrier and rear-surface passivation materials.
4. Thermally anneal the dielectric paste (for example, at approximately 500-1000° C. for approximately 5 to 30 minutes).
5. Perform phosphorus diffusion preferably using a gaseous source (e.g., POCl₃, PH₃, etc.). This diffusion is preferably an intermediate diffusion; that is, light enough to provide a good spectral response on the front surface, but heavy enough to provide sufficient doping for the n-type contact.
6. Perform etch to remove phosphorous oxide glass left by the diffusion. Suitable etchants are well known in the industry, and can include aqueous HF chemical etch, HF vapor etch, or various plasma etchant chemistries.
7. Deposit a silicon nitride layer or other high-refractive index material (e.g., TiO₂ and Ta₂O₅) on the front surface to form an antireflection coating with a thickness that depends upon the refractive index and the desired color, of around 70 to 80 nm. The silicon nitride is preferably deposited by plasma-enhanced chemical vapor deposition (PECVD) as an amorphous alloy containing silicon, nitrogen, and hydrogen (sometimes designated a-SiNₓ:H or SiNₓ:H). These films are well known to provide passivation of the surface and bulk defects, and thereby improve the energy-conversion efficiency of the silicon solar cell.
8. Deposit a silicon nitride or other dielectric layer on the rear surface, preferably SiNₓH (optional). This layer passivates the rear surface and thereby improves the solar cell efficiency. This step may be performed simultaneously with step 7, or after step 10.
9. Screen print metal for the p-type contact and grid (“p-metal”), preferably using a paste (preferably Ag—Al, or optionally Ag or Al);
10. Dry the p-metal;
11. Screen print metal for the n-type contact and grid (preferably Ag), preferably about 10 to 50 microns thick;
12. Fire the metal; and
13. Test the solar cell.
   In this method, the p-type metal preferably spikes the phosphorus (n+) diffusion in the dielectric-barrier openings in order to make the ohmic contacts. A schematic of such a configuration is depicted in FIG. 18. The advantage of this process over the prior art is that only one phosphorous diffusion is required, and the holes are drilled at the beginning of the process (which eliminates a laser damage etch step), reducing process cost.

Back-contact EWT cells may also be fabricated with processes similar to a buried-contact cell fabrication sequence using self-doping metallizations. Care must be taken to ensure that the self-doping metallizations fill the grooves and holes so that series resistance is not a problem. One example of such a process is as follows:

1. Etch and clean the Si wafer;

2. Laser scribe n-type grooves and drill holes on rear surface;

3. Light (80 to 120 ohms/sq) phosphorus diffusion;

4. HF etch to remove phosphorus glass from diffusion process;

5. Silicon nitride deposition by, for example, PECVD or low-pressure chemical vapor deposition (LPCVD);

6. Laser scribe p-type grooves or pits on rear surface;

7. Fill n-type grooves/hole and p-type grooves with n-type and p-type self-doping metallizations, respectively; and

8. Co-fire metallizations.

In any of the above embodiments, the large areas of SiN or other dielectric on the rear surface enables the contact lines, which are preferably interdigitated, to be as wide as possible (in order to carry more current) without actually contacting the silicon wafer. They also enable the maximization of n⁺ emitter while minimizing the area of the p-type contacts, thereby increasing carrier collection efficiency. The percentage of the total rear surface area occupied by the p-type contacts

Further, in all of the embodiments herein, numerous methods or variations may be used, including but not limited to the following. The vias can be formed using laser drilling, although alternative methods such as chemical or plasma etching, thermomigration, etc. may be used. Some of these methods are described in U.S. patent application Ser. No. 10/880,190, entitled “Emitter Wrap-Through Back Contact Solar Cells on Thin Silicon Wafers”, U.S. patent application Ser. No. 10/606,487, entitled “Fabrication of Back-Contacted Solar Cells Using Thermomigration to Create Conductive Vias”, and International Patent Application Serial No. PCT/US04/20370, entitled “Back-Contacted Solar Cells with Integral Conductive Vias and Method of Making”, all of which are incorporated herein by reference. Etching paste may be screen printed to perform fine patterning. Borosilicate glass or another p-type dopant source may be used to form the p⁺ junction. The choice of size of the scribed grooves must be balanced between reducing the contact area and minimizing the recombination velocity. Finally, a selective emitter process may also be utilized, where the diffusion is lighter on the front surface than in the vias or on the back surface. This can be accomplished, for example, by screen printing a porous SiO₂ layer on the front surface, which retards phosphorus diffusion on the front surface while the holes and rear surface are heavily diffused, and is etched off by, for example, HF. This can alternatively be accomplished by loading wafers with their front surfaces face to face in a single slot (i.e., double loading) in the POCl₃ furnace, which reduces the diffusion on the touching surfaces.

All these sequences can be used for making back-junction in addition to EWT cells very simply—the laser simply scribes pits or grooves rather than drill holes for the n-type contact. A back-junction solar cell has both the negative- and positive-polarity current-collection junctions on the rear surface. These cells require high quality material so that the photogenerated carriers absorbed near the front surface can diffuse across the width of the device to be collected at the junctions on the rear of the device.

Minimizing the Series Resistance in an Interdigitated Back Contact Grid Pattern

Because back-contact silicon solar cells have both the negative-polarity and positive-polarity contacts and current-collection grids on the back surface, the negative-polarity and positive-polarity grids must be electrically isolated from one another. The grids must also collect the current to bonding pads or busbars. Metallic ribbons are typically attached to the bonding pads or busbars in order to connect the solar cells into an electrical circuit.

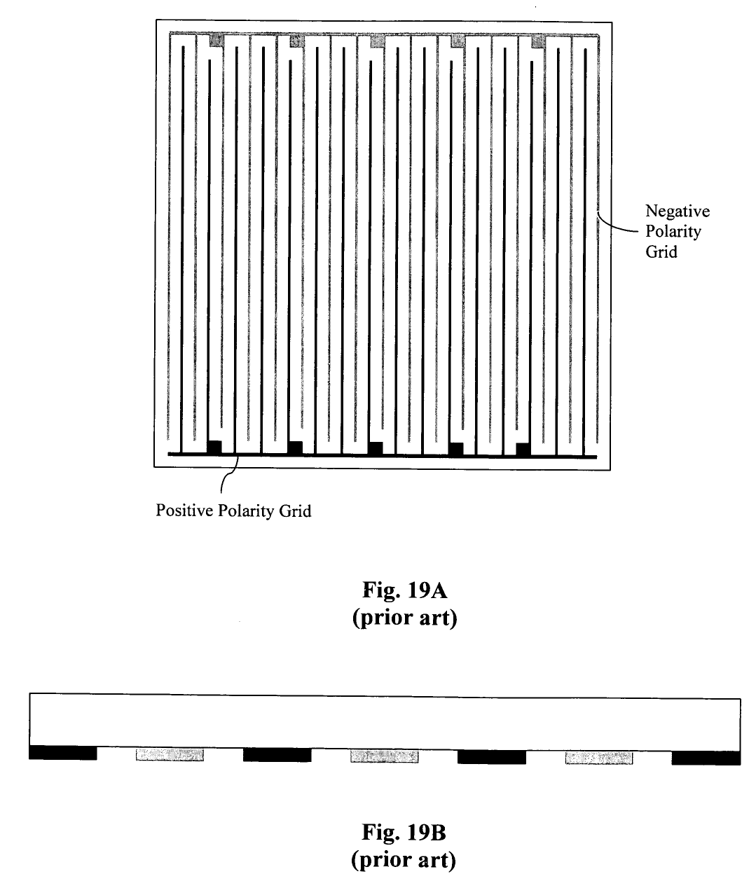

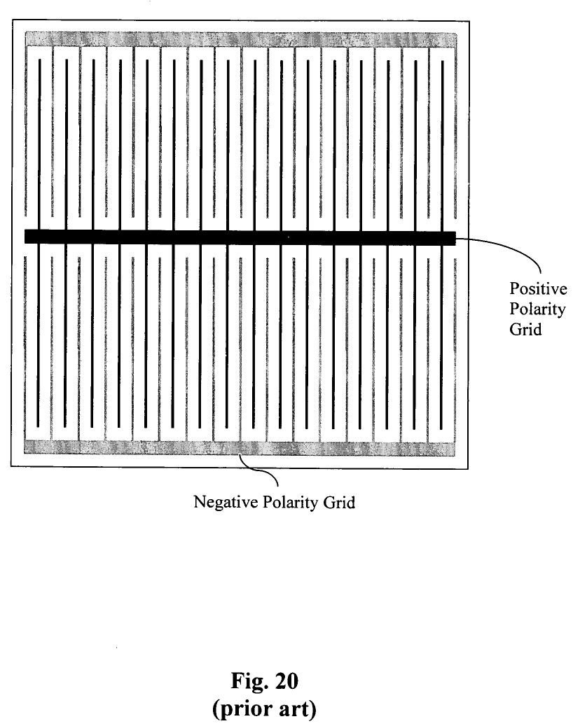

There are two geometries for the grids in a back-contact cell. In an “interdigitated back contact” (IBC) geometry, the negative- and positive-conductivity type grids form interdigitated comb-like structures (FIGS. 19A and 19B). This structure is simple to implement in production, but suffers from high series resistance due to the long grid lines with limited cross sectional area. The length of the grid lines, and therefore the series resistance, can be reduced by including one or more busbars (FIG. 20). However, the busbars reduce the effective active area because photocurrent collection is reduced in region above the busbar. Also, the geometry for interconnecting adjacent back-contact solar cells becomes more complex for cells with busbars in the center of the cell rather than bonding pads at the edge of the cell. IBC patterns can be easily produced using low-cost production techniques like screen printing.

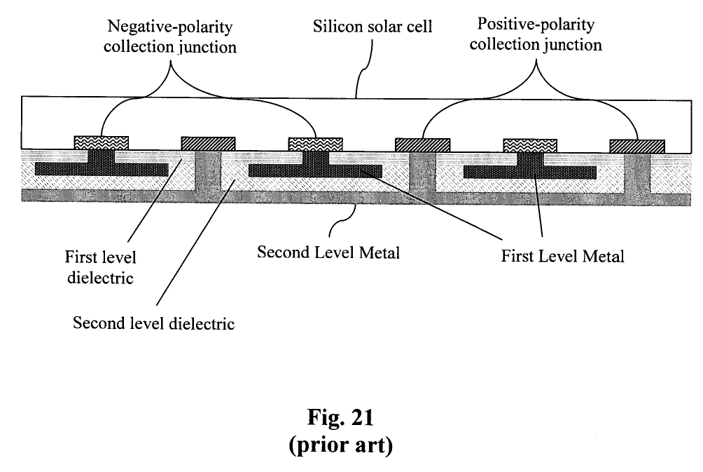

The second geometry for the grids in a back-contact cell uses a multilevel metallization (FIG. 21) (Richard M. Swanson, “Thermophotovoltaic converter and cell for use therein,” U.S. Pat. No. 4,234,352, issued Nov. 18, 1980). The metal levels are stacked vertically with deposited dielectric layers providing electrical isolation. Multilevel metallization geometry can achieve a lower series resistance than the IBC geometry because metal covers the entire rear surface. However, this structure requires two dielectric depositions (“first” and “second” level) and patterning steps in addition to the metallization steps. In addition, multilevel metallizations require very costly thin-film processing techniques in order to avoid pinhole defects in the dielectric isolation layer that could lead to electrical shunts.

The present invention provides two embodiments for minimizing the series resistance of the preferred IBC grid pattern (with the bonding pads at the edge of the cell) in an interdigitated back contact grid pattern of a back-contact silicon solar cell.

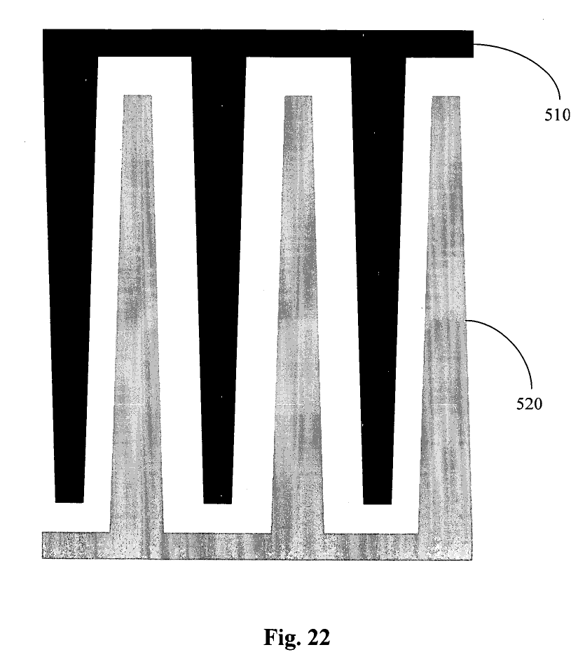

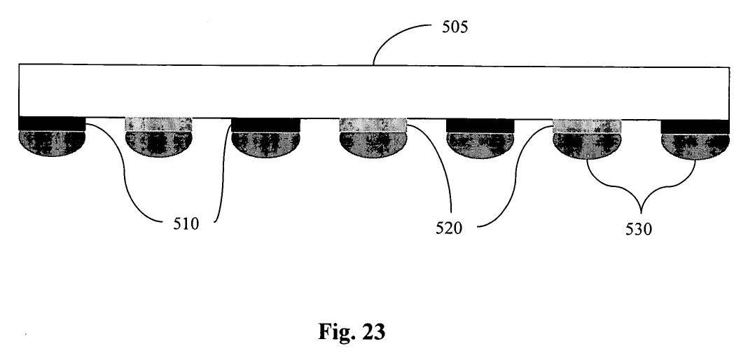

In a first embodiment, the grid lines are made with a tapered width—such that the width is increased along the direction of current flow until it reaches the edge of the cell. This reduces the series resistance at a constant grid coverage fraction because the cross-sectional area of the grid increases at the same rate that the current carried by the grid increases. A preferred embodiment of the tapered width pattern in both positive-polarity current-collection grid 510 and negative-polarity current-collection grid 520 is shown in FIG. 22 (not to scale). FIG. 23 shows a cross-sectional view of the IBC grids of FIG. 22 on the back surface of solar cell 505 with plated metallization; that is, metal 530 plated over the contact metallizations.

In general, the degree of tapering may be determined either empirically or by calculation, to determine an optimal tapering. Additionally, the metal coverage fraction and the spacing between same-polarity grids may similarly be varied. In a simulation of an IBC cell with typical properties, the series resistance of an IBC grid was calculated for a 125-mm by 125-mm cell. The spacing between same-polarity grids was selected to be 2 mm, and the metal coverage fraction was selected to be 40%. The grid lines had a width of 400 μm for the constant-width IBC geometry, while the grid lines increased from 200 to 600 μm for the tapered geometry. The series resistance was 36% less for the tapered versus the constant-width IBC geometry. Note that other tapers may be used as required; for example, the grid line might taper from 250 to 550 μm wide.

In a second embodiment, the grid resistance can be reduced by making the grid lines thicker. The thickness of screen-printed Ag paste grids is limited by the physical properties of the paste and screen. The preferred geometry for the IBC grid permitting edge collection (FIG. 19A) typically requires relatively thick grid lines (>50 μm) in order to be able to conduct current over the large dimensions with acceptable resistance losses. This is thicker than can be easily screen printed. Two preferred methods of increasing the grid line thickness of the printed Ag IBC grid are: by dipping the IBC cell into molten solder (“tin dipping”) or by plating (electro- or electroless) of metal onto the grid lines. Tin dipping is a well known process that is used by some silicon solar cell manufacturers for fabrication of conventional silicon solar cells. The temperature of the molten solder depends upon the composition of the solder, but is generally less than 250° C. In one embodiment a Sn:Ag solder is employed in order to minimize dissolution of the printed Ag grid line.

Alternatively, many metals can be plated via electro- or electroless plating. Cu and Ag are particularly advantageous in that both metals can be readily soldered to and have excellent electrical conductivity. Another advantage of plated grid lines is reduced stress in the completed cell. A thin printed Ag line may preferably be used since the final conductivity will be determined by the subsequent metal buildup step. Ag is fired at a high temperature (generally above 700° C.), so keeping this layer thin reduces stress from the high firing temperature. In addition, plating is generally performed at low temperatures (<100° C.). The grid thickness thus can be increased at a lower temperature, thereby introducing less stress to the completed cell.

The preceding examples can be repeated with similar success by substituting the generically or specifically described reactants and/or operating conditions of this invention for those used in the preceding examples. In particular, one of skill in the art will recognize that certain of the process steps may be modified, their order changed, or additional steps added, without deviating from the scope of the invention.

Although the invention has been described in detail with particular reference to these preferred embodiments, other embodiments can achieve the same results. Variations and modifications of the present invention will be obvious to those skilled in the art and it is intended to cover all such modifications and equivalents. The entire disclosures of all references, applications, patents, and publications cited above, and of the corresponding applications, are hereby incorporated by reference.

What is claimed is:

1. A method for making a back-contact solar cell, the method comprising the steps of:
providing a semiconductor substrate comprising a first conductivity type;
providing a diffusion comprising an opposite conductivity type on the rear surface;
depositing a dielectric layer on the rear surface;
forming a plurality of holes extending from a front surface of the substrate to a rear surface of the substrate;
removing the diffusion and dielectric layer from one or more regions of the rear surface;
creating one or more contacts comprising the first conductivity type in each of the one or more regions;
disposing a first conductive grid on the rear surface in electrical contact with the contacts; and
disposing a second conductive grid on the rear surface in electrical contact with the diffusion in the holes.

2. The method of claim 1 wherein the creating step comprises doping the substrate with a dopant.

3. The method of claim 2 wherein the dopant comprises an element selected from the group consisting of boron and aluminum.

4. The method of claim 2 wherein the first conductive grid does not comprise the dopant.

5. The method of claim 1 wherein the step of providing a diffusion comprises exposing the substrate to a gas.

6. The method of claim 5 wherein the gas comprises POCl₃.

7. The method of claim 1 wherein the first conductive grid is interdigitated with the second conductive grid.

8. The method of claim 1 wherein the depositing step comprises depositing the dielectric layer on the front surface and the creating step comprises simultaneously providing a second diffusion comprising an opposite conductivity type on the interior surfaces of the holes.

9. The method of claim 1 further comprising the step of constructing a passivation layer on one or both of the front surface and the rear surface.

10. The method of claim 9 wherein the constructing step comprises a method selected from the group consisting of oxidizing the surface or depositing the passivation layer on the surface.

11. The method of claim 1 further comprising the step of coating the interior surfaces of the holes and the one or more region with a plated metallic contact layer, wherein the coating step is performed after the creating step and prior to the disposing steps.

12. The method of claim 11 wherein the contact layer comprises nickel.

13. The method of claim 11 wherein the contact layer is plated using electroless plating.

14. The method of claim 11 further comprising the step of providing a second diffusion after the removing step, the second diffusion comprising an opposite conductivity type on the interior surfaces of the holes and the one or more regions; wherein the creating step comprises overdoping the second diffusion.

15. A back contact solar cell made according to the method of claim 1.

16. A back contact solar cell comprising a plated layer comprising a metal, said layer disposed between one or more doped regions of the substrate and one ore more conductive grids, wherein said conductive grids do not comprise the metal.

17. The back contact solar cell of claim 16 wherein said metal comprises nickel.

18. A method for making a back-contact solar cell, the method comprising the steps of:
providing a semiconductor substrate comprising a first conductivity type;
depositing a patterned dielectric layer on the rear surface;
providing a diffusion comprising an opposite conductivity type on open portions of the rear surface not covered by the dielectric layer;
disposing a metal on the open portions and on the dielectric layer adjacent to the open portions; and
firing the metal.

19. The method of claim 18 wherein the depositing step comprises screen printing the dielectric layer.

20. The method of claim 18 wherein the step of providing a diffusion comprises using a gas selected from the group consisting of POCl₃ and PH₃.

21. The method of claim 18 wherein the metal comprises a dopant of the first conductivity type.

22. The method of claim 21 wherein the disposing step comprises screen printing a paste comprising the metal.

23. The method of claim 18 wherein the firing step comprises spiking the diffusion in the open portions with the metal.

24. A back-contact solar cell made according to the method of claim 18.
